(19) United States
(12) Patent Application Publication
(10) Pub. No.: US 2009/0050997 A1
(43) Pub. Date: Feb. 26, 2009

(54) Solid-state image capturing device, manufacturing method for the solid-state image capturing device, and electronic information device

(75) Inventor: Akiyoshi Mutoh, Hiroshima (JP)

Correspondence Address: Edwards Angell Palmer & Dodge LLP, P.O. Box 55874, Boston, MA, 02205, US

(73) Assignee: Sharp Kabushiki Kaisha, Osaka-shi (JP)

(21) Appl. No.: 12/222,100

(22) Filed: Aug. 1, 2008

(30) Foreign Application Priority Data
Aug. 3, 2007 (JP) 2007-203473

(51) Int. Cl. H01L 31/00; H01L 21/00

(52) U.S. Cl. 257/440; 438/69; 257/E31.001; 257/E21.001

(57) ABSTRACT

A solid-state image capturing device having a plurality of light receiving sections for performing photoelectrical conversion on and capturing image light from a subject is provided. In the light receiving sections, a low concentration opposite conductivity layer is provided either on a single conductivity substrate or a single conductivity layer, a high concentration opposite conductivity layer having a higher impurity concentration than the low concentration opposite conductivity layer is provided on the low concentration opposite conductivity layer, and a photodiode is constituted by a PN junction of the single conductivity substrate or the single conductivity layer and the low concentration opposite conductivity layer.

This Nonprovisional Application claims priority under 35 U.S.C. §119(a) on Patent Application No. 2007-203473 filed in Japan on Aug. 3, 2007, the entire contents of which are hereby incorporated by reference.

### BACKGROUND OF THE INVENTION

1. Field of the Invention

The present invention relates to a solid-state image capturing device having a plurality of light receiving sections arranged in two dimensions for performing photoelectric conversion on image light from a subject and capturing an image of the subject; a manufacturing method for the solid-state image capturing device, and an electronic information device, such as a digital camera (e.g., digital video camera and digital still camera), an image input camera, a scanner, a facsimile machine and a camera-equipped cell phone device, having the solid-state image capturing device as an image input device used in an image capturing section of the electronic information device.

2. Description of the Related Art

The conventional solid-state image capturing device described above is mounted in a digital camera, a cell phone device and the like, and such a solid-state image capturing device includes a CCD image sensor using a CCD (Charge Coupled Device) and a CMOS image sensor, which is compatible with a CMOS manufacturing process and has a lower driving voltage compared with the CCD image sensor.

FIG. 10 is a longitudinal cross sectional view schematically showing an exemplary structure of a basic pixel in the conventional CMOS image sensor disclosed in Reference 1.

In FIG. 10, on a high concentration P⁺ substrate 101, a P-type layer 102 having an impurity concentration lower than that of the P⁺ substrate 101 is provided, and an N-type photoelectric conversion region 103 for connecting with the P-type layer 102 to form a photodiode is provided on the P-type layer 102. As a result, a basic pixel 100 of the conventional CMOS image sensor is formed. Preferably, the P-type layer 102 is formed on the P⁺ substrate 101 by epitaxial growth. In addition, the N-type photoelectric conversion region 103 is formed, for example, by ion implantation or by diffusion of an N-type impurity.

Herein, the impurity concentration for the P+substrate 101 ranges, for example, from 1×10¹⁸/cm³ to 1×10²²/cm³, the impurity concentration for the P-type layer 102 ranges, for example, from 1×10¹⁶/cm³ to 1×10¹⁸/cm³. Further, the impurity concentration for the N-type photoelectric conversion region 103 ranges, for example, from 1×10¹⁸/cm³ to 1×10²²/cm³.

In addition, a surface P⁺ layer 104 is formed on a surface side of P-type layer 102 and the N-type photoelectric conversion region 103 in order to prevent a leakage on the surface of the N-type photoelectric conversion region 103. Further, in order to separate the basic pixel 100 from adjacent basic pixels, a P⁺-type element separation region 105 formed in the P-type layer 102, an element separation oxide film 106 formed on the P⁺-type element separation region 105 and the like, a gate oxide film 107 provided on the surface P⁺ layer 104, an interlayer insulation film 108 formed on the element separation oxide film 106 and a gate oxide film 107 so as to cover all of them, and a shading film 109 for preventing light from entering unnecessary portion formed in the interlayer insulation film 108 are provided.

In the basic pixel 100, the thickness of the P-type layer 102 is set ranging from approximately 2 μm to 10 μm. That is, the length from the principal surface of the semiconductor to an interface between the P-type layer 102 and the P⁺ substrate 101 is set to range from greater than or equal to 2 μm to less than or equal to 10 μm. This depth of greater than or equal to 2 μm and less than or equal to 10 μm is almost the same as the optical absorption length of a red or near infrared region in a silicon. The thickness of the P-type layer 102 can be varied in accordance with a wavelength of light that needs to be sensed.

When incident light enters a photodiode, which is formed by a PN junction of the N-type photoelectric conversion region 103 and the P-type layer 102 therebelow, electron and positive hole pairs are generated due to the incident light in a region of the N-type photoelectric conversion region 103 and the P-type layer 102 therebelow during a signal charge accumulation. The generated electrons are then accumulated in a depletion layer formed in a portion of the N-type photoelectric conversion region 103 and the P-type layer 102 therebelow. At this stage, among the photoelectrons generated in the P-type layer 102, photoelectric conversion electrons diffused towards below the substrate flow from the P-type layer 102 to the P⁺ substrate 101 side and are captured because the P⁺ substrate 101, whose impurity concentration is higher than that of the P-type layer 102, is arranged below the P-type layer 102. The electrons are re-combined here and disappear. With this structure, the diffusion of electrons in a transverse direction to adjacent pixels is controlled through the P⁺ substrate 101 in the basic pixel 100. As a result, it is possible to reduce cross talk between pixels and control the decline of image resolution.

Reference 1: Japanese Laid-Open Publication No. 2002-170945

### SUMMARY OF THE INVENTION

In the conventional structure described above, the N-type photoelectric conversion region 103 is provided on the P-type layer 102, the P-type layer 102 formed on the P⁺ substrate 101, which is a high concentration P-type substrate, and the P-type layer 102 having a lower concentration than that of the P⁺ substrate 101. The photoelectric conversion electrons in a deep region of the low concentration P-type layer 102 flow into the P⁺ substrate 101 having higher impurity concentration than the low concentration P-type layer 102 and are captured. As a result, the electron diffusion in a transverse direction to adjacent pixels is controlled and cross talk between unit pixels 100 is reduced, thereby controlling the decline of image resolution. However, due to further miniaturization of a region for next generation light receiving sections, the amount of signal charges (the number of electrons) contributing to photoelectric conversion decreases in the N-type photoelectric conversion region 103 for each unit pixel 100 forming a light receiving section. In addition, in a deep region of the low concentration P-type layer 102, photoelectric conversion electrons (signal charges) flow from the low concentration P-type layer 102 to the P⁺ substrate 101 side. Therefore, it is difficult to improve sensitivity (photoelectric conversion efficiency) for green color to red color, for which photoelectric conversion is performed in a deep location of the low concentration P-type layer 102.

The present invention is intended to solve the conventional problems described above. The objective of the present invention is to provide a solid-state image capturing device, where sensitivity is improved, including sensitivity (photoelectric conversion efficiency) for green color to red color and cross talk of signal charges to adjacent pixels is further reduced; a manufacturing method for the solid-state image capturing device; and an electronic information device using the solid-state image capturing device as an image input device in an image capturing section.

A solid-state image capturing device according to the present invention has a plurality of light receiving sections for performing photoelectrical conversion on and capturing image light from a subject, in which, in the plurality of light receiving sections, a low concentration opposite conductivity layer is provided either on a single conductivity substrate or a single conductivity layer, a high concentration opposite conductivity layer having a higher impurity concentration than the low concentration opposite conductivity layer is provided on the low concentration opposite conductivity layer, and a photodiode includes a PN junction of the single conductivity substrate or the single conductivity layer and the low concentration opposite conductivity layer, thereby achieving the objective described above.

Preferably, in a solid-state image capturing device according to the present invention, the low concentration opposite conductivity layer is added in a substrate depth direction below the high concentration opposite conductivity layer to expand a photoelectric conversion region in volume.

Still preferably, in a solid-state image capturing device according to the present invention, the high concentration opposite conductivity layer and the low concentration opposite conductivity layer are provided such that electric potential is inclined to flow photoelectric conversion electron from the low concentration opposite conductivity layer to the side of the high concentration opposite conductivity layer.

Still preferably, in a solid-state image capturing device according to the present invention, the high concentration opposite conductivity layer is provided in a region with a substrate depth of up to and including 0.5 μm.

Still preferably, in a solid-state image capturing device according to the present invention, the low concentration opposite conductivity layer is provided in a region with a substrate depth ranging approximately 0.5 μm to 2 μm.

Still preferably, in a solid-state image capturing device according to the present invention, a depletion layer is extended to a deeper side of the single conductivity substrate or the single conductivity layer at a PN junction section between the low concentration opposite conductivity layer and the single conductivity substrate or the single conductivity layer.

Still preferably, in a solid-state image capturing device according to the present invention, a depletion layer is extended 2 μm to 3 μm in a depth direction side of the single conductivity substrate or the single conductivity layer at a PN junction section between the low concentration opposite conductivity layer and the single conductivity substrate or the single conductivity layer.

Still preferably, in a solid-state image capturing device according to the present invention, the electric potential is successively inclined gradually from an electric potential of −3 to −4 V of the high concentration opposite conductivity layer to an electric potential of less than 0V of the PN junction section between the low concentration opposite conductivity layer and either the single conductivity substrate or the single conductivity layer.

Still preferably, in a solid-state image capturing device according to the present invention, the low concentration opposite conductivity layer includes a region where photoelectric conversion is performed on a wavelength ranging between a green color light and a red color light.

Still preferably, in a solid-state image capturing device according to the present invention, the single conductivity substrate or the single conductivity layer is either a silicon substrate or a silicon layer, and a thickness range of the low concentration opposite conductivity layer includes an absorption length of light ranging from green to red in silicon.

Still preferably, in a solid-state image capturing device according to the present invention, a multi-step implantation is performed for the high concentration opposite conductivity layer.

Still preferably, in a solid-state image capturing device according to the present invention, the multi step implantation is performed in two steps in a depth direction of an upper impurity region and a lower impurity region, or in three steps in a depth direction of an upper impurity region, intermediate impurity region and a lower impurity region, and the upper impurity region is provided in a position where a distance to a region for reading out a signal charge is shorter than that of the lower impurity region.

Still preferably, in a solid-state image capturing device according to the present invention, impurity ion implantation to the upper impurity region and the impurity region lower than the upper impurity region is performed by changing an implantation direction having a predetermined angle.

Still preferably, in a solid-state image capturing device according to the present invention, implantation impurity for the high concentration opposite conductivity layer has a greater mass than implantation impurity for the low concentration opposite conductivity layer.

Still preferably, in a solid-state image capturing device according to the present invention, implantation impurity for the high concentration opposite conductivity layer is arsenic (As), and implantation impurity for the low concentration opposite conductivity layer is phosphorus (P).

Still preferably, in a solid-state image capturing device according to the present invention, multi step implantation is performed for the low concentration opposite conductivity layer below the high concentration opposite conductivity layer so as to perform ion implantation deeper.

Still preferably, in a solid-state image capturing device according to the present invention, the multi step implantation is performed in two steps in a depth direction of an upper impurity region and a lower impurity region, or in three steps in a depth direction of an upper impurity region, an intermediate impurity region and a lower impurity region.

A solid-state image capturing device according to the present invention is a CMOS solid-state image capturing device, wherein the plurality of light receiving sections are provided in two dimensions in an image capturing region, a signal charge converted in each light receiving section is read out in a signal voltage converting section, and a signal amplified according to signal voltage converted in the signal voltage converting section is read out for each pixel as an output signal, thereby achieving the objective described above.

Preferably, in a solid-state image capturing device according to the present invention, as a two pixel sharing structure, one signal readout circuit is commonly provided via a floating diffusion for two light receiving sections and two transfer transistors for reading out signal charges in correspondence with the two light receiving sections.

Still preferably, in a solid-state image capturing device according to the present invention, the signal readout circuit includes a selection transistor for selecting a predetermined light receiving section among a plurality of light receiving sections that are arranged in a matrix; an amplifying transistor connected in series to the selection transistor, for amplifying a signal in accordance with the signal voltage into which a signal charge is converted, the signal charge being transferred from a selected light receiving section to the floating diffusion via the transfer transistor; and a reset transistor for resetting electric potential of the floating diffusion to a predetermined electric potential after a signal output from the amplifying transistor.

A solid-state image capturing device according to the present invention is a CCD solid-state image capturing device, wherein the plurality of light receiving sections are provided in two dimensions in an image capturing region, and a photoelectrically converted signal charge in each light receiving section is read out to a charge transfer section and successively transferred in a predetermined direction, thereby achieving the objective described above.

Still preferably, in a solid-state image capturing device according to the present invention, the single conductivity layer is formed as a low concentration single conductivity well layer having single conductivity impurity ion-implanted to a predetermined depth, on an opposite conductivity substrate or an opposite conductivity layer.

A manufacturing method for a solid-state image capturing device according to the present invention includes: a high concentration opposite conductivity impurity ion implantation step of forming a high concentration opposite conductivity layer in a light receiving section forming region, an overall plural pixel region, or a plurality of belt shaped plural pixel regions in either row or column direction; a low concentration opposite conductivity impurity ion implantation step of forming a low concentration opposite conductivity layer below the high concentration opposite conductivity layer in a light receiving section forming region, an overall plural pixel region, or a plurality of belt shaped plural pixel regions in either a row or a column direction; and a pixel separation step of separating light receiving sections by selectively implanting single conductivity impurity ion with a predetermined pattern, which is performed after performing the two previous steps in either this order or a reversed order, thereby achieving the objective described above.

Preferably, in a manufacturing method for a solid-state image capturing device according to the present invention, the high concentration opposite conductivity impurity ion implantation step forms a high concentration impurity layer by ion-implanting a first opposite conductivity impurity having a first impurity concentration by using a mask having openings for the overall plural pixel region, or the plurality of belt shaped plural pixel regions in either row or column direction.

Still preferably, in a manufacturing method for a solid-state image capturing device according to the present invention, the low concentration opposite conductivity impurity ion implantation step forms a low concentration impurity layer by ion-implanting a second opposite conductivity impurity having a first impurity concentration by using a mask having openings for the overall plural pixel region, or the plurality of belt shaped plural pixel regions in either row or column direction.

Still preferably, in a manufacturing method for a solid-state image capturing device according to the present invention, the pixel separation step selectively ion-implants a single conductivity impurity by using a mask having an opening to separate the periphery of the light receiving section, and separates the periphery of the light receiving section with an element separation region to define the periphery of the region of the light receiving section.

A manufacturing method for a solid-state image capturing device according to the present invention further includes an STI step of separating the periphery of the light receiving section with an insulation material on the single conductivity substrate or the single conductivity layer, as a preceding step of the high concentration opposite conductivity impurity ion implantation step and the low concentration opposite conductivity impurity ion implantation step.

Preferably, in a manufacturing method for a solid-state image capturing device according to the present invention, the STI step includes: a trench groove forming step of forming a trench groove to separate the periphery of the light receiving section on the single conductivity substrate or the single conductivity layer, a step of forming an element separating insulation film to embed the trench groove, and a step of polishing the formed element separating insulation film to planarize a substrate surface.

A manufacturing method for a solid-state image capturing device according to the present invention further includes a gate electrode forming step of forming a gate electrode for transferring an electric charge, as a post-step of the pixel separation step.

A manufacturing method for a solid-state image capturing device according to the present invention further includes a surface single conductivity region forming step of ion-implanting a single conductivity impurity in a surface of the high concentration opposite conductivity layer to form the surface single conductivity region.

An electrical information device according to the present invention uses the solid-state image capturing device according to the present invention as an image input device in an image capturing section, thereby achieving the objective described above.

The functions of the present invention having the structures described above will be described hereinafter.

According to the present invention, a low concentration opposite conductivity layer having lower impurity concentration than that of a high concentration opposite conductivity layer is provided deep inside a substrate below a high concentration opposite conductivity layer which forms a light receiving section. Further, a photodiode is formed deep inside the substrate by PN junction of a single conductivity substrate or a single conductivity layer below the low concentration opposite conductivity layer.

With such a structure, even if a light receiving area of a light receiving section is reduced, the light receiving section can be formed even deeper in the substrate and the light receiving section can be expanded in volume to secure the amount of signal charges. In addition, it is possible to improve sensitivity including the color sensitivity (photoelectric conversion efficiency) for green color to red color even in a deep region of the substrate, and it is possible to increase a saturation charge capacity (the maximum number of stored electrons).

Because the low concentration opposite conductivity layer is provided under the high concentration opposite conductivity layer and the inclination of energy level (electric potential) is set such that the photoelectric conversion electrons generated in the low concentration opposite conductivity layer deep in the substrate flow to the high concentration opposite conductivity layer, the photoelectric conversion electrons flow from a conductivity layer, which is of the same conductivity type as the type on the substrate side, to the substrate as conventionally, thereby further reducing cross talk of signal charges (electrons) to the adjacent left and right pixels.

In addition, in a manufacturing method for the solid-state image capturing device according to the present invention, an opposite conductivity impurity ion implantation for forming a high concentration opposite conductivity layer in a light receiving section forming region, an overall plural pixel region, or a plurality of belt shaped plural pixel regions in either row or column direction, and the same type of opposite conductivity impurity ion implantation for forming a low concentration opposite conductivity layer in an overall plural pixel region or a plurality of belt shaped plural pixel regions in either row or column direction are performed. Subsequently, a single conductivity impurity ion implantation for separating pixels is performed, and an element separation section is formed between light receiving sections. Therefore, there is no need to consider a margin for a shifted implant location at the time of forming the light receiving section, compared to a conventional method where a single conductivity region and an opposite conductivity region are defined in sections from the beginning and then ion implantation is performed. As a result, it is possible to form each light receiving area in a wider range.

According to the present invention with the structure described above, a low concentration opposite conductivity layer having an impurity concentration lower than that of a high concentration opposite conductivity layer is formed below the high concentration opposite conductivity layer that constitutes a light receiving section so as to form a photodiode deep inside a substrate. Therefore, even if a light receiving section area is miniaturized for a solid-state image capturing device in a next generation, the light receiving section can be expanded in volume to secure the amount of signal charges. In addition, it is possible to improve sensitivity including the color sensitivity (to improve photoelectric conversion efficiency) for green color to red color even in a deep region of the substrate, and it is possible to increase a saturation capacity (the maximum number of stored electrons). Further, because the low concentration opposite conductivity layer is formed below the high concentration opposite conductivity layer, electrons of the low concentration opposite conductivity layer deep in the substrate flow to the side of the high concentration opposite conductivity layer and gather together, reducing the cross talk of signal charges to adjacent pixels.

Further, a high concentration opposite conductivity layer is formed in a light receiving section forming region, an overall plural pixel region, or a plurality of belt shaped plural pixel regions in either row or column direction, and the impurity ion implantation is performed all together for forming a low concentration opposite conductivity layer in an overall plural pixel region or a plurality of belt shaped plural pixel regions in either row or column direction. Subsequently, a single conductivity impurity ion implantation for separating pixels is performed. Therefore, there is no need to consider a margin for a shifted implant location at the time of forming the light receiving section, compared to a conventional case where a single conductivity region and an opposite conductivity region are defined in sections from the beginning and then ion implantation is performed. As a result, it is possible to form each light receiving area in a wider range.

These and other advantages of the present invention will become apparent to those skilled in the art upon reading and understanding the following detailed description with reference to the accompanying figures.

### BRIEF DESCRIPTION OF THE DRAWINGS

FIG. 1 is a longitudinal cross sectional view schematically showing a structural principle of a unit pixel in a solid-state image capturing device according to Embodiment 1 of the present invention.

FIG. 2 is a circuit diagram showing a unit pixel of a solid-state image capturing device having a two pixel shared structure in a CMOS image sensor according to Embodiment 2 of the present invention.

FIG. 3 is a plan view schematically showing an exemplary plan structure including a plurality of unit pixels of the solid-state image capturing device in FIG. 2.

FIG. 4 is a cross sectional view along the line X-X′ schematically showing a unit pixel of the solid-state image capturing device of FIG. 3.

FIG. 5 is a potential contour diagram corresponding to cross sectional locations of essential portions in the unit pixel of the solid-state image capturing device of FIG. 4.

FIG. 6 is a potential contour diagram corresponding to cross sectional locations of essential portions in the unit pixel of a conventional solid-state image capturing device, FIG. 6 being a referential example for a comparison with FIG. 5.

FIG. 7 is a diagram showing electric potential in the depth of a substrate in a transverse axis location X1 in FIG. 5.

FIG. 8 is a longitudinal cross sectional view schematically showing a unit pixel of a solid-state image capturing device in a CCD image sensor according to Embodiment 3 of the present invention.

FIG. 9 is a block diagram showing an exemplary essential structure of the electronic information device according to Embodiment 4 of the present invention.

FIG. 10 is a longitudinal cross sectional view schematically showing an exemplary structure of a basic pixel in the conventional CMOS image sensor disclosed in Reference 1.

10, 10A, 10B unit pixel
1 single conductivity substrate or single conductivity layer
2 low concentration opposite conductivity layer
3 high concentration opposite conductivity layer
4 element separation section
11, 12, 30 photodiode
13, 14 transfer transistor
13a, 14a, 38 gate
15 signal readout circuit
16 selection transistor
17 amplifying transistor
18 reset transistor
19 signal line
21, 31 N-type semiconductor substrate
22, 32 low concentration P-type well
23, 33 high concentration P-type layer
24, 34 low concentration N-layer
25, 35 high concentration N-layer
26, 36 high concentration P-type layer for separating elements
26a, 36a STI
27, 37 surface P+ layer
33a charge readout section
50 electronic information device
51 solid-state image capturing device
52 signal processing section
53 memory section
54 display section
55 communication section
FD floating diffusion
TF charge transfer section

### DESCRIPTION OF THE PREFERRED EMBODIMENTS

Hereinafter, a basic principle of a solid-state image capturing device according to the present invention and a manufacturing method for the solid-state image capturing device will be described as Embodiment 1. A case where the solid-state image capturing device according to Embodiment 1 of the present invention and the manufacturing method of the same are applied to a CMOS image sensor will be described as Embodiment 2. A case where the solid-state image capturing device according to Embodiment 1 of the present invention and the manufacturing method of the same are applied to a CCD image sensor will be described as Embodiment 3. Further, an electronic information device using any one of the solid-state image capturing devices according to Embodiments 1 to 3 as an image input device in an image capturing section, will be described as Embodiment 4. All of the embodiments will be described with reference to the accompanying figures.

Herein, the characteristics of the CMOS image sensor and the CCD image sensor will be briefly described.

The CMOS image sensor is similar to the CCD image sensor in that photoelectric conversion elements (light receiving sections) corresponding to pixels are two dimensionally arranged in the CMOS image sensor. However, unlike the CCD image sensor, the CMOS image sensor does not use a CCD for transferring a signal charge from each light receiving section with a vertical transfer section and transferring the signal charge from the vertical transfer section in a horizontal direction with a horizontal transfer section. Instead, the CMOS image sensor reads out a signal charge from the light receiving section for each pixel with a selection control line formed by an aluminum wiring like a memory device and converts the signal charge into voltage. Subsequently, the CMOS image sensor successively reads out an imaging signal amplified in accordance with the converted voltage from a selected pixel. On the other hand, the CCD image sensor requires a plurality of positive and negative power supply voltages for driving a CCD, whereas the CMOS image sensor is capable of driving itself with a single power supply, which enables a low electric consumption and low voltage driving compared with the CCD image sensor. Further, because a unique CCD manufacturing process is used for manufacturing the CCD image sensor, it is difficult to apply a manufacturing process generally used for a CMOS circuit directly to the manufacturing method for the CCD image sensor. On the other hand, the CMOS image sensor uses a manufacturing process generally used for the CMOS circuit. Therefore, a logic circuit, an analog circuit and an analog-digital conversion circuit and the like can be simultaneously formed by the CMOS process that is frequently used for manufacturing a driver circuit for controlling a display, a driver circuit for controlling image capturing, a semiconductor memory such as DRAM, and a logic circuit. That is, it is easy to form a CMOS image sensor on a same semiconductor chip on which a semiconductor memory, a driver circuit for controlling a display, and a driver circuit for controlling image capturing are formed. In addition, with respect to the manufacturing for the CMOS image sensor, it is easy for the CMOS image sensor to share a production line with the semiconductor memory, the driver circuit for controlling a display, and the driver circuit for controlling image capturing.

### Embodiment 1

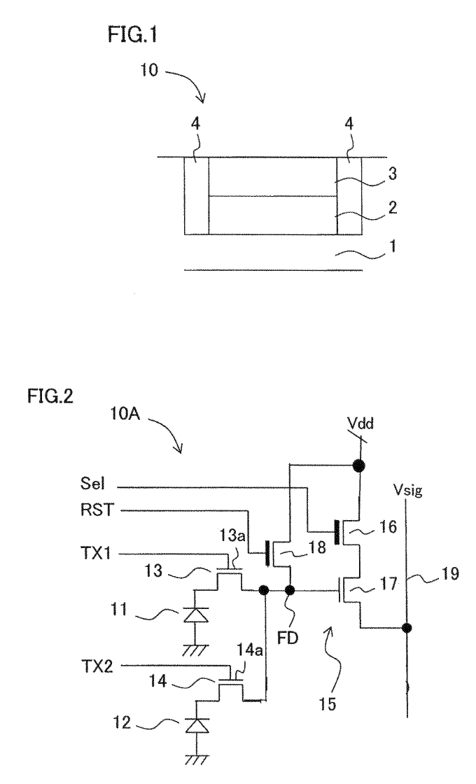

FIG. 1 is a longitudinal cross sectional view schematically showing a structural principle of a unit pixel in a solid-state image capturing device according to Embodiment 1 of the present invention.

According to FIG. 1, in a light receiving section (photoelectric conversion section) in an unit pixel 10 of the solid-state image capturing device according to Embodiment 1, a low concentration opposite conductivity layer 2 is provided on a single conductivity substrate or single conductivity layer 1. On the low concentration opposite conductivity layer 2, a high concentration opposite conductivity layer 3 having a higher impurity concentration than that of the low concentration opposite conductivity layer 2 is provided, and a photodiode is formed deep inside the substrate by a PN junction of the single conductivity layer 1 and the low concentration opposite conductivity layer 2.

As described above, by providing the low concentration opposite conductivity layer 2 having a impurity concentration lower than that of the high concentration opposite conductivity layer 3 in a region deeper than the high concentration opposite conductivity layer 3, the light receiving section can be expanded in volume even if a light receiving section area, in which photoelectric conversion is performed, is further miniaturized for a solid-state image capturing device in a next generation. In addition, a photoelectric conversion electron, to which direction it flows is unknown from the region of the low concentration opposite conductivity layer 2 deeper than the bottom of the high concentration opposite conductivity layer 3, can be efficiently drawn from the low concentration opposite conductivity layer 2 having a lower impurity concentration to the side of the high concentration opposite conductivity layer 3 to be accumulated.

As described above, the low concentration opposite conductivity layer 2 is provided at the bottom of the high concentration opposite conductivity layer 3 so that the inclination of the energy level (electric potential) is set to smoothly flow the photoelectric conversion electron from the PN junction section with either the single conductivity substrate or layer 1 to the low concentration opposite conductivity layer 2 to the side of the high concentration opposite conductivity layer 3. As a result, it is possible to improve sensitivity including the color sensitivity (to improve photoelectric conversion efficiency) for green color to red color and to increase a saturation capacity (the maximum number of stored electrons), and to reduce the cross talk of a signal charge to adjacent pixels.

In a manufacturing method for the solid-state image capturing device according to the present invention, an opposite conductivity impurity ion implantation is performed to form the high concentration opposite conductivity layer 3 in a light receiving section forming region, an overall image capturing region (an overall plural pixel region), or a plurality of belt shaped plural pixel sections (plural pixel regions) in either a row or a column direction. Further, the same opposite conductivity impurity ion implantation is performed to form the low concentration opposite conductivity layer 2 in an overall image capturing region (an overall plural pixel region) or a plurality of belt shaped plural pixel sections (plural pixel regions) in either a row or a column direction are performed. Subsequently, a single conductivity impurity ion implantation for separating pixels is performed, a circumference of the light receiving section is separated by a single conductivity type element separation section 4, and the light receiving section can be formed by defining sections for the light receiving section. Therefore, there is no need to consider a margin for an ion implant location between the light receiving section and the element separation section 4, compared to a conventional method where a single conductivity region (element separation section) and an opposite conductivity region of the light receiving section are defined in sections from the beginning and then ion implantation is performed. As a result, it is possible to form each light receiving area of each light receiving section in a wider range.

### Embodiment 2

FIG. 2 is a circuit diagram showing a unit pixel of a solid-state image capturing device having a two pixel shared structure in a CMOS image sensor according to Embodiment 2 of the present invention.

According to FIG. 2, in a unit pixel section 10A in the solid-state image capturing device having a two pixel shared structure in a CMOS image sensor according to Embodiment 2, photodiodes 11 and 12 functioning as two light receiving sections and two transfer transistors 13 and 14 for reading out a signal charge corresponding to the respective photodiodes 11 and 12 are provided, and one common signal readout circuit 15 is also provided for the two photodiodes and two transfer transistors.

The readout circuit 15 includes a selection transistor 16 as a pixel selection section, an amplifying transistor 17 for amplifying a signal in accordance with a signal charge voltage of a floating diffusion FD of a selected pixel, connected in series to the selection transistor 16 and functioning as a signal amplification section, and a reset transistor 18 for resetting an electric potential of the floating diffusion FD to a predetermined electric potential. The readout circuit 15 successively transfers signal charges from two top and bottom photodiodes 11 and 12 to the floating diffusion FD to convert the electric charge into voltage. In accordance with the converted signal voltage, the amplifying transistor 17 in a pixel selected by the selection transistor 16 amplifies the signal so that a signal line 19 successively reads out the signal as an image capturing pixel signal for each pixel. Subsequently, the floating diffusion FD is reset to the predetermined electric potential of a power supply voltage Vdd by the reset transistor 18.

The photodiodes 11 and 12 performs photoelectric conversion to convert incident light into a signal charge in accordance to the amount of the light. Transfer transistors 13 and 14 functioning as a charge transfer section (transfer gate) are respectively provided between the respective photodiodes 11 and 12 and the floating diffusion FD.

Charge transfer control signals TX1 and TX2 are provided to gates 13a and 14a of the respective transfer transistors 13 and 14 via a charge transfer control line for transferring an electric charge, and signal charges (photoelectric conversion electrons) photoelectrically converted by the photodiodes 11 and 12 are successively transferred to the floating diffusion FD.

The gate of the amplifying transistor 17 is connected to the floating diffusion FD, and a series of the selection transistor 16 and the amplifying transistor 17 are connected between the power supply line and the signal line 19. The amplifying transistor 17 has a source follower type amplifier structure. In addition, the power supply line is electrically connected to the floating diffusion FD via the reset transistor 18, and the electric potential of the floating diffusion FD is periodically reset to the predetermined electric potential of the power supply voltage Vdd and the like after the reading out to the signal line 19 and before the reading out of the signal charge to the floating diffusion FD.

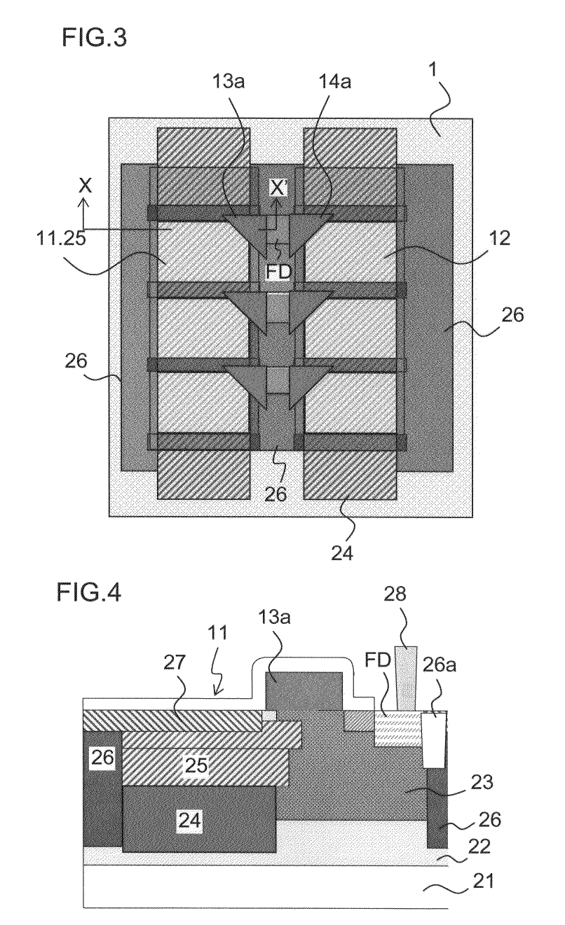

FIG. 3 is a plan view schematically showing an exemplary structure including a plurality of unit pixels of the solid-state image capturing device in FIG. 2. FIG. 4 is a cross sectional view along the line X-X′ schematically showing an unit pixel of the solid-state image capturing device of FIG. 3.

According to FIG. 3 and FIG. 4, in each pixel section 10A of the solid-state image capturing device according to Embodiment 1, a low concentration P-type well 22 is provided on a substrate section of an N-type semiconductor substrate 21. In a region directly under a gate electrode 13 (channel formation region) the region including above the low concentration P-type well 22, and the region avoiding the contact with the photodiode 11, a P-type layer 23 having a higher concentration than the low concentration P-type well 22 is provided. In addition, a low concentration N-layer 24 functioning as a low concentration opposite conductivity layer is provided in each light receiving region in the low concentration P-type well 22 and the high concentration P-type layer 23, and a high concentration N-layer 25 is provided functioning as a high concentration opposite conductivity layer having an impurity concentration higher than that of the low concentration N-layer 24. The photodiode 11 functioning as a photoelectric conversion section described in FIG. 2 is formed by the low concentration N-layer 24 and the high concentration N-layer 25 in the low concentration P-type well 22 and the high concentration P-type layer 23. Adjacent to the photodiode 11, a charge transfer section (transistor channel section) of a charge transfer transistor for transferring a signal charge to the floating diffusion FD is provided on the high concentration P-type layer 23.

A gate electrode (gate 13a), which is a triangular extraction electrode (charge transfer electrode) in a plan view covering a corner of the rectangular photodiode 11, is provided on the high concentration P-type layer 23 of the charge transfer section between the floating diffusion FD and the high concentration N-layer 25 via a gate insulation film (now shown). Further, a signal readout circuit (not shown) is provided for every two unit pixel 10A, where the signal charge transferred from the photodiode 11 to the floating diffusion section FD is converted into voltage and amplification is performed in accordance with the converted voltage and the signal readout circuit reads out an imaging signal for each pixel.

Further, a high concentration P-type layer 26 for separating elements and having an impurity concentration higher than that of the high concentration P-type layer 23, and an STI 26a are provided in a surrounding manner along the periphery of the region of two unit pixels 10A that are formed of photodiodes 11 and 12 functioning as light receiving sections, gates 13a and 14a and the floating diffusion FD between the gates 13a and 14a.

Further, a surface P+ layer 27 is provided on the high concentration N-layer 25 so that the low concentration N-layer 24 and the high concentration N-layer 25 constituting the photodiode 11 to prevent a dark current will have an embedded structure. In short, the low concentration N-layer 24 and the high concentration N-layer 25 are embedded in the low concentration P-type well 22 and the high concentration P-type layer 23 by the surface P+ layer 27, the gate 13a and the high concentration P-type layer 26.

Above the gates 13a and 14a, a plurality of circuit wirings such as the signal readout circuit described above (not shown) and interlayer insulation films are alternately provided. For example, the floating diffusion FD is connected to the upper wiring via a contact 28 and the upper wiring is connected to the gate of the amplifying transistor 17. Further, on the wirings, color filters of respective R, G and B colors are formed in a corresponding manner to the respective light receiving sections. Further, microlenses for condensing light to corresponding light receiving sections are arranged above.

The signal charges photoelectrically converted by the photodiodes 11 and 12 are transferred by the transfer transistors 13 and 14 from the photodiodes 11 and 12 to the floating diffusion FD, and the signal charges are converted from charge to voltage here. According to the converted voltage, signal amplification is performed to be read out by the signal line 19. However, even if the photodiodes 11 and 12 are formed as a high concentration N region 3 even deeper by a multi level implantation, a barrier for a transfer path will not be lowered even a predetermined charge transfer voltage is applied in a deep portion of the substrate, and a higher charge transfer voltage is required to be applied. As a result, it is difficult to read out electric charges without applying a higher voltage as charge transfer voltage to the gate 13a and 14a. On the contrary, by providing the low concentration N-layer 24 in a location deeper than the high concentration N-layer 25, a depletion layer can be extended under the low concentration N-layer 24 while a high voltage driving is avoided and charge transferring is performed under advantageous conditions.

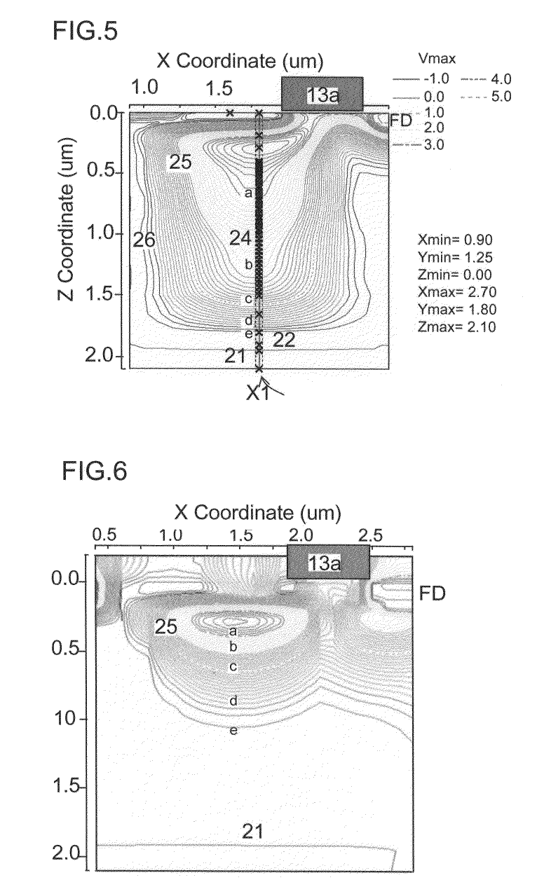

FIG. 5 is a potential structural diagram corresponding to cross sectional locations of essential portions in the unit pixel of the solid-state image capturing device of FIG. 4. FIG. 6 is a referential example for a comparison with FIG. 5, and is a potential structural diagram corresponding to cross sectional locations of essential portions in the unit pixel of a conventional solid-state image capturing device. In FIGS. 5 and 6, a longitudinal axis (Z) indicates a depth of the substrate, with the upper end showing a surface of the substrate, and the transverse axis (X) indicates a direction along the substrate plane, with the locations of the reference numerals in the respective figures corresponding to the locations of the reference numerals of the members in FIG. 4.

As shown in FIGS. 5 and 6, the high concentration N-layer 25 is about 0.5 μm in depth and the center portion of the high concentration N-layer 25 is 0.3 μm in depth in the unit pixel 10A according to Embodiment 2. On the other hand, the low concentration N-layer 24 is at most about 2 μm in depth and the center portion is 1.0 μm in depth. Substantially, photoelectric conversion electrons in the depth of about 2 μm to 3 μm can be accumulated in the high concentration N-layer 25 because the depletion layer at the PN junction section with the low concentration P-type well 22 is further extended from the depth of 2 μm of the low concentration N-layer 24.

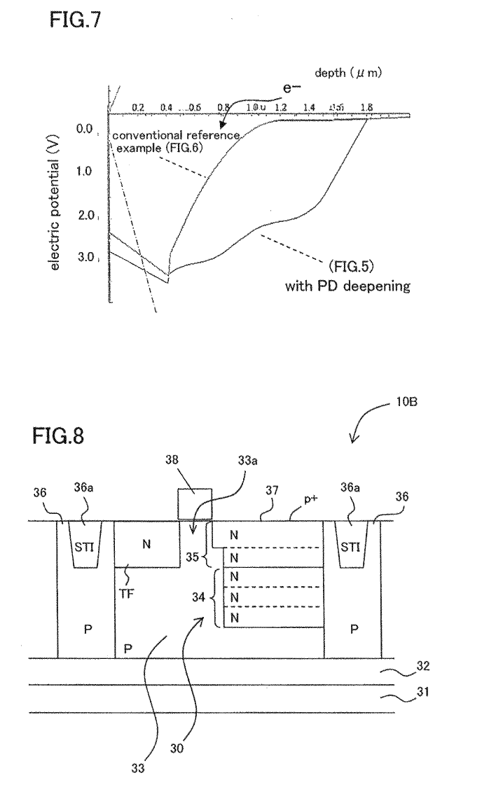

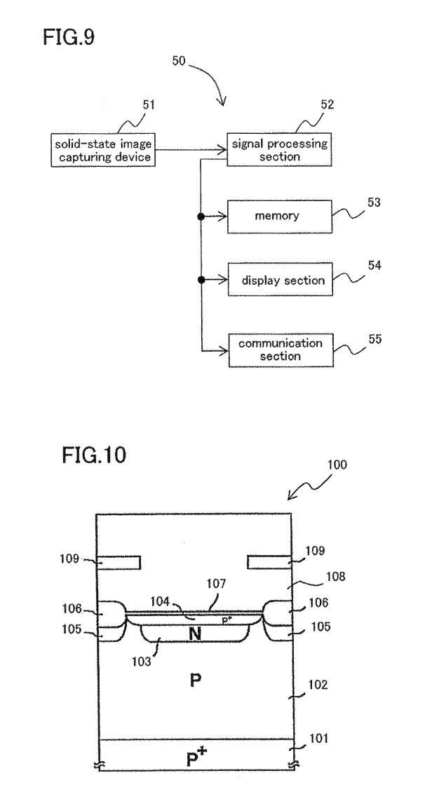

In FIGS. 5 and 6, electric potential of −3 to −4 V exists deep up to and including the location a and N-type electric potential is strong, which is a region where electrons are easy to exist. The electric potential region of −2 to −3 V is up to and including the location b, the electric potential region of −1 to −2 V is up to and including the location c, the electric potential region of 0 to −1 V is up to and including the location d, and the electric potential region of less than 0 V is up to and including the location e. Compared to the reference example of FIG. 6, according to Embodiment 2, the inclination of the electric potential exists deeply inside the substrate due to the low concentration N-layer 24, and it can be recognized that the inclination of the electric potential is set such that photoelectric conversion electrons flow smoothly to the sides of low concentration P-type well 22, the low concentration N-layer 24, and the high concentration N-layer 25. Such an inclination of the electric potential is shown in FIG. 7.

FIG. 7 is a diagram showing electric potential in the depth of the substrate in a transverse axis location X1 in FIG. 5.

As shown in FIG. 7, the case with the conventional reference example of FIG. 6 shows that only the photoelectric conversion electrons in a shallower substrate depth can be accumulated to the side of the high concentration N-layer 25 compared to the case of the unit pixel 10A according to Embodiment 2 of FIG. 5. However, in the case with the unit pixel 10A according to Embodiment 2 of FIG. 5, the low concentration N-layer 24 is provided below the high concentration N-layer 25, so that the profile of the electric potential in FIG. 5 can be set such that an inclination is produced in the electric potential such that the photoelectric conversion electrons flow smoothly from the location of the low concentration N-layer 24 in a deep substrate depth up to 0.5 μm of the substrate depth of the side of the high concentration N-layer 25 and the photoelectric conversion electrons are accumulated on the high concentration N-layer 25b side.

Herein, the unit pixel section 10A of the solid-state image capturing device having a two pixel shared structure in the CMOS image sensor of Embodiment 2 can be manufactured as follows. With respect to the unit pixel 10A, a plurality of the unit pixels 10A are actually arranged in a two dimensional matrix in an image capturing region of the solid-state image capturing device. Herein, only one unit pixel section 10A is indicated for the sake of simplicity.

First, an STI 26a for separating elements is formed.

In the STI forming step, an SiO₂ film is formed by thermally oxidizing an n-type silicon, for example, on a surface of the N-type semiconductor substrate 21, which is an n-type silicon substrate. On the SiO₂ film, an SiN film is formed as a protection film by low pressure CVD. Further, a photoresist mask is patterned using a photolithography technique on a pixel region where a photodiode section, for example, is desired to be formed. Using the photoresist mask, the SiO₂ film and the SiN film corresponding to an element separation region are etched by dry etching and patterned. Further, Si substrate is etched using the SiN film as a mask to form a trench groove of 350 nm deep, for example. Subsequently, a sacrificial oxidization film is formed by oxidizing a surface portion inside a trench groove la at 850 degrees Celsius in an oxygen atmosphere in order to remove a surface defect layer due to the etching. Subsequently, the sacrificial oxidization film is removed. The surface portion of the trench groove is rough at the time of forming the trench groove. However, a sacrificial oxidization film is formed by oxidizing the inner surface of the trench groove, and the sacrificial oxidization film is removed with fluorine. As a result, crystal defect on the surface is removed and the surface is cleaned. Subsequently, an HDP film is formed by a CVD method as an element separation insulation film to embed the trench groove. The HDP film is polished by a CMP method to planarize the substrate surface and remove a SiN film 3 on the surface. The periphery of the light receiving section region is separated by an element separating insulation film. The STI 26a for defining the light receiving section region is formed. Because adjacent light receiving sections are electrically separated by a high concentration P-type layer which will be described later, the SIT may be formed only in a direction where the floating diffusion exists (left and right direction in a plan view), instead of forming the STI on the four edges of the light receiving section region. Further, an HDP film may be embedded in the trench groove as an element separating insulation film after forming the high concentration P-type layer 26.

Next, boron (B) is implanted as a p-type impurity into the N-type semiconductor substrate 21, which is composed of n-type silicon, up to a predetermined depth to form the low concentration P-type well 22. Further, a well known photolithography technique is used and a resist pattern is used as a mask, the resist pattern including a region where a gate electrode 13 is to be formed and a region opened without including the light receiving section region, so that boron (B) is implanted up to a predetermined depth to form a region above the low concentration P-type well 22, or the high concentration P-type layer 23 having a higher concentration than the low concentration P-type well 22.

Further, the high concentration N-layer 25 on a shallow side is formed.

In a high concentration N-type impurity ion implantation step, using a well known photolithography technique and using a resist pattern, in which a region for forming a light receiving section is opened, as a mask, arsenic (As) is ion-implanted with impurity concentration of 5×10¹⁶/cm³ to 1×10¹⁸/cm³, so that the high concentration N-layer 25 on the shallow side is formed. In this case, the formation of the high concentration N-layer 25 is performed in two steps changing the degree of inclination of the ion implantation direction (seven degrees). First, ion implantation is performed with the ion implantation direction of a seven degree incline away from the side of the gate 13a to be formed later at the implantation depth of 0.12 to 0.25 μm and the implantation concentration of 1 to 2×10¹²/cm² to form a high concentration N-layer on the upper side. Subsequently, ion implantation is performed with the ion implantation direction tilted towards the side of the gate 13a to be formed later (in a direction getting under the gate 13a) at the implantation depth of 0.05 to 0.12 μm and the implantation concentration of 2.5 to 4×10¹²/cm² to form a high concentration N-layer on the lower side. As a result, a region having a substrate depth ranging 0 to 0.5 μm is formed in the two of the lower high concentration N-layer and the upper high concentration N-layer in the high concentration N-layer 25. The upper high concentration N-layer is formed closer to an end portion of an active region in the floating diffusion FD than the lower high concentration N-layer, so that a low voltage transfer driving is possible for signal charges. The high concentration N-type impurity ion implantation step may be performed using a resist pattern, in which a region is opened in an overall plural pixel region or in a plurality of belt shaped plural pixel regions in either a row or a column direction (overall image capturing region or a plurality of belt shaped plural pixel sections in either row or column direction), as a mask. Such a case is more preferable because a resist processing will be easy.

Further, the low concentration N-layer 24 on the deeper side is formed.

In a low concentration N-type impurity ion implantation step, using a resist pattern, in which a region is opened in an overall plural pixel region or in a plurality of belt shaped plural pixel regions in either row or column direction (overall image capturing region or a plurality of belt shaped plural pixel sections in either row or column direction), as a mask, phosphorus (P), which is lighter than arsenic (As), is implanted with impurity concentration of 5×10¹⁵/cm³ to 5×10¹⁷/cm³ in the even deeper substrate depth, so that the low concentration N-layer 24 on the deeper side is formed. In this case, the formation of the low concentration N-layer 24 is performed in three steps in the substrate depth direction. First, the first ion implantation is performed in a region of the substrate depth ranging 0.7±0.1 μm with the implantation concentration of 0.3 to 3×10¹²/cm² to form an upper low concentration N-layer. Subsequently, the second ion implantation is performed in a region of the substrate depth ranging 1±0.1 μm with the implantation concentration of 0.2 to 1.5×10¹²/cm² to form an intermediate low concentration N-layer. Further, the third ion implantation is performed in a region of the substrate depth ranging 1.4±0.1 μm with the implantation concentration of 0.5 to 3.5×10¹²/cm² to form a lower low concentration N-layer. As a result, the low concentration N-layer 24 is formed of the three of the upper low concentration N-layer, the intermediate low concentration N-layer and the lower low concentration N-layer. As a result, in the electric potential in FIG. 7, a smooth inclination is formed without forming a potential barrier or a potential well in the electric potential so that the photoelectric conversion electrons flow smoothly from the low concentration N-layer 24 to the side of the high concentration N-layer 25 and the photoelectric conversion electrons are accumulated to the side of the high concentration N-layer 25. As a result, charge transfer with low voltage is possible. In addition, the high concentration N-layer 25 is formed in the substrate depth ranging 0 to 0.5 μm, and the low concentration N-layer 24 is formed by expanding a region as deep as possible to a deep location in the substrate after forming the high concentration N-layer 25. Because arsenic (As) has a mass greater than phosphorus (P), the arsenic (As) is difficult to move and therefore, easy to control the region. The multi-step implantation is used to perform an ion implantation as deep as possible. The ion implantation is performed in such a condition to smoothen the electric potential without having electric potential build-up in the middle of the electric potential by the multi step implantation.

Subsequently, a high concentration P-type layer 26 is formed as an element separation section in such a manner that the STI 26a is positioned at the center section of element separation in the plan width direction.

In an element separation step, using a resist pattern, where a region is selectively opened to separate the periphery of the light receiving section region, as a mask, P-type impurity ion (B) (or indium In) is implanted with the impurity concentration of 5×10¹⁶/cm³ to 1×10¹⁹/cm³, the periphery of the light receiving section is separated by a P-type element separation region, and the periphery of the light receiving section region is defined. In this case, the implantation for separating elements is performed in four steps in the substrate depth direction. First, the first ion implantation is performed in a region of the substrate depth ranging 0.7±0.1 μm with the implantation concentration of 2 to 6E12/cm². Subsequently, the second ion implantation is performed in a region of the substrate depth ranging 1±0.1 μm with the implantation concentration of 2 to 6×10¹²/cm². Further, the third ion implantation is performed in a region of the substrate depth ranging 1.4±0.1 μm with the implantation concentration of 2 to 6×10¹²/cm² and then performed in a region of the substrate depth ranging 0.2±0.15 μm with the implantation concentration of 3 to 8×10¹²/cm². Due to this implantation, the P-type impurity is implanted into the N-type region to change the N-type region into the P-type region. As a result, there is no need to consider a margin for the location of ion implantation between the light receiving section and the element separation region, and the light receiving area in each light receiving section can be formed in a wider range.

Next, a gate electrode (gate 13a) for transferring an electric charge is formed.

After a gate insulation film (not shown) is formed on the substrate surface by a well known technique such as thermal oxidation, a conductivity material film is formed on a substrate section. Further, above that, a resist pattern, where a region of a photodiode including the low concentration N-layer 24 and the high concentration N-layer 25, and the active region of the floating diffusion FD are opened and a gate region for transferring an electric charge is covered to keep the region, is used as a mask, the conductivity material film is etched, and the gate electrode (gate 13a) is formed in a predetermined shape as a charge transfer electrode.

Further, the surface P+ layer 27 is formed.

In a surface P-type region forming step, in order to form an embedded photodiode, a resist pattern having a predetermined pattern and a gate electrode (gate 13a) are used as a mask, and boron is ion-implanted in the surface of the high concentration N-layer 25 that constitutes a photodiode in a depth ranging 0.01 to 0.05 μm with the implantation concentration of 5×10¹² to 3×10¹³/cm². As a result, the surface P+ type region having as much impurity concentration as 1×10¹⁷/cm³ to 1×10¹⁹/cm³ is formed.

Further, the active region of the floating diffusion FD is formed.

A resist pattern, where a region to be an active region of the floating diffusion FD is opened, is used as a mask, and arsenic (As) is ion-implanted in a depth ranging 0.01 to 0.2 μm with the implantation concentration of 1×10¹³ to 5×10¹⁵/cm². As a result, the active region of the floating diffusion FD having as much impurity concentration as 5×10¹⁶/cm³ to 1×10²²/cm³ is formed.

Subsequently, wiring formation is carried out, and a color filter and a microlens are formed.

Although not shown in the figures, after a plurality of metal wiring sections and interlayer film sections are alternately formed above the gate electrode (gate 13a), a corresponding color filter is formed above the photodiode region. Further, after a planarization film is formed, a microlens is formed in a corresponding manner to the photodiode region. As a result, a CMOS type solid-state image capturing device can be manufactured.

According to Embodiment 2 with the structure described above, the low concentration N-layer 24 is formed below the high concentration N-layer 25 in the CMOS type solid-state image capturing device. Therefore, even if a light receiving section area is miniaturized for a solid-state image capturing device in a next generation, the light receiving section can be expanded in volume to secure the amount of signal charges. In addition, it is possible to improve sensitivity including the color sensitivity (to improve photoelectric conversion efficiency) for green color to red color even in a deep region of the substrate, and it is possible to increase a saturation capacity (the maximum number of stored electrons). Further, because the low concentration N-layer 24 is formed below the high concentration N-layer 25, electrons of the low concentration N-layer 24 in the deep substrate depth flow to the side of the high concentration N-layer 25 and to be accumulated, reducing the conventional cross talk of signal charges to adjacent pixels.

### Embodiment 3

FIG. 8 is a longitudinal cross sectional view schematically showing a unit pixel of a solid-state image capturing device in a CCD image sensor according to Embodiment 3 of the present invention.

In FIG. 8, a low concentration P-type well 32 is provided on a substrate section of an N-type semiconductor substrate 31 in each unit pixel 10B of a CCD image sensor according to Embodiment 3. A P-type layer 33 having a higher concentration than the low concentration P-type well 32 is provided on the low concentration P-type well 32. In addition, a low concentration N-layer 34 functioning as a low concentration opposite conductivity layer is provided for every light receiving region in a plan view in the low concentration P-type well 32 and the high concentration P-type layer 33. A high concentration N-layer 35 is provided on the low concentration N-layer 34, the high concentration N-layer 35 functioning as a high concentration opposite conductivity layer and having a higher impurity concentration than the low concentration N-layer 34. A photodiode 30, which functions as a photoelectric conversion section for performing photoelectric conversion on incident light to generate a signal charge, is formed by the low concentration N-layer 34 and the high concentration N-layer 35 in the low concentration P-type well 32. A charge readout section 33a (transistor channel section) for transferring the signal charge to a charge transfer section TF is provided by the P-type layer 33, the charge readout section 33a being adjacent to the photodiode 30.

On the charge readout section 33a, a gate 38 is successively arranged via a gate insulation film (not shown) in a predetermined direction, functioning as a charge transfer electrode for reading out a signal charge and controlling a charge transfer. Although the gate 38 is provided on the charge readout section 33a, it may be provided on the charge transfer section TF and the charge readout section 33a to function not only as a gate for reading out an electric charge but also as a vertical charge transfer gate.

Further, a high concentration P-type layer 36 for separating elements, which has a higher impurity concentration than the P-type layer 33 is provided along the region of the unit pixel 10B including the photodiode 30 as a light receiving section and the gate 38 to surround it, and an STI 36a functioning as an element separating insulation region is provided at the center section of the high concentration P-type layer 36 in the width direction.

Further, in order to prevent a dark current, a surface P+ layer 37 for making a low concentration N-layer 34 and the high concentration N-layer 35 for constituting the photodiode 30 serve as an embedded structure, are provided on the upper side of the high concentration N-layer 35. In short, the low concentration N-layer 34 and the high concentration N-layer 35 are embedded in the low concentration P-type well 32 and the P-type layer 33 by the surface P+ layer 37, the gate 38 and the high concentration P-type layer 36.

The unit pixel section 10B of the solid-state image capturing device in the CCD image sensor according to Embodiment 3 can be manufactured as follows. Note that a plurality of unit pixel sections 10B are actually arranged in a two dimensional matrix in an image capturing region of the solid-state image capturing device. Herein, only one unit pixel section 10B is indicated for the sake of simplicity.

First, the STI 36a for separating elements is formed.

In the STI forming step, an SiO₂ film is formed by thermally oxidizing an n-type silicon, for example, of a surface of the N-type semiconductor substrate 21, which is an n-type silicon substrate. On the SiO₂ film, an SiN film is formed as a protection film by low pressure CVD. Further, a photoresist mask is patterned using a photolithography technique on a pixel region where a photodiode section, for example, is desired to be formed. Using the photoresist mask, the SiO₂ film and the SiN film corresponding to an element separation region are etched by dry etching and patterned. Further, Si substrate is etched using the SiN film as a mask to form a trench groove of 350 nm deep, for example. Subsequently, a sacrificial oxidization film is formed by oxidizing a surface portion inside a trench groove la at 850 degrees Celsius in an oxygen atmosphere in order to remove a surface defect layer due to the etching. Subsequently, the sacrificial oxidization film is removed. The surface portion of the trench groove is rough at the time of forming the trench groove. However, a sacrificial oxidization film is formed by oxidizing the inner surface of the trench groove, and the sacrificial oxidization film is removed with fluorine. As a result, crystal defect on the surface is removed and the surface is cleaned. Subsequently, an HDP film is formed by a CVD method as an element separation insulation film to embed the trench groove. The HDP film is polished by a CMP method to planarize the substrate surface and remove a SiN film 3 on the surface. The periphery of the light receiving section region is separated by an element separating insulation film. The STI 26a for defining the light receiving section region is formed. In addition, an HDP film may be embedded in the trench groove as an element separating insulation film after forming the high concentration P-type layer 36.

Next, boron (B) is ion-implanted as a p-type impurity into the N-type semiconductor substrate 31, which is composed of n-type silicon, up to and including a predetermined depth to form the low concentration P-type well 32. Further, in order to form a region above the low concentration P-type well 32, boron (B) is ion-implanted up to and including a predetermined depth to form the high concentration P-type layer 33 having a higher concentration than the low concentration P-type well 32.

Further, the high concentration N-layer 35 and the charge transfer region TF on a shallow side is formed.

In a high concentration N-type impurity ion implantation step, using a well known photolithography technique and using a resist pattern, in which a region for forming a light receiving section is opened, as a mask, arsenic (As) is ion-implanted with impurity concentration of 5×10¹⁶/cm³ to 1×10¹⁸/cm³, so that the high concentration N-layer 25 on the shallow side is formed. In this case, the formation of the high concentration N-layer 25 is performed in two steps changing the ion implantation direction. First, ion implantation is performed with the ion implantation direction of a seven degree incline away from the side of the gate 38 to be formed later at the implantation depth of 0.12 to 0.25 μm and the implantation concentration of 1 to 2×10¹²/cm² to form a high concentration N-layer on the upper side. Subsequently, ion implantation is performed with the ion implantation direction tilted towards the side of the gate 38 to be formed later (in a direction getting under the electrode) at the implantation depth of 0.05 to 0.12 μm and the implantation concentration of 2.5 to 4×10¹²/cm² to form a high concentration N-layer on the lower side. As a result, a region having a substrate depth ranging 0 to 0.5 μm is formed in the two of the lower high concentration N-layer and the upper high concentration N-layer in the high concentration N-layer 35. The upper high concentration N-layer is formed closer to the side of an end portion of an active region in the charge transfer section TF than the lower high concentration N-layer, so that a low voltage transfer driving is possible for signal charges. The high concentration N-type impurity ion implantation step may be performed using a resist pattern, in which a region is opened in an overall plural pixel region or in a plurality of belt shaped plural pixel regions in either row or column direction (overall image capturing region or a plurality of belt shaped plural pixel sections in either row or column direction), as a mask. Such a case is more preferable because a resist processing will be easy.

In this case, a resist pattern, which is selectively opened in a plurality of belt shaped regions in either row or column direction, is used as a mask, and arsenic (As) is implanted with the impurity concentration of 1×10¹⁶ to 1×10¹⁸/cm³, so that the charge transfer section TF is simultaneously formed.

Further, the low concentration N-layer 34 on the deeper side is formed.

In a low concentration N-type impurity ion implantation step, using a resist pattern, in which a region is opened in a plurality of belt shaped plural pixel sections (plural pixel regions) in either row or column direction, as a mask, phosphorus (P), which is lighter than arsenic (As), is ion-implanted with impurity concentration of 5×10¹⁵/cm³ to 5×10¹⁷/cm³ in the even deeper substrate depth, so that the low concentration N-layer 34 on the deeper side is formed. In this case, the formation of the low concentration N-layer 34 is performed in three steps in the substrate depth direction. First, the first ion implantation is performed in a region of the substrate depth ranging 0.7±0.1 μm with the implantation concentration of 0.3 to 3×10¹²/cm² to form an upper low concentration N-layer. Subsequently, the second ion implantation is performed in a region of the substrate depth ranging 1±0.1 μm with the implantation concentration of 0.2 to 1.5×10¹²/cm² to form an intermediate low concentration N-layer. Further, the third ion implantation is performed in a region of the substrate depth ranging 1.4±0.1 μm with the implantation concentration of 0.5 to 3.5×10¹²/cm² to form a lower low concentration N-layer. As a result, the low concentration N-layer 34 is formed of the three of the upper low concentration N-layer, the intermediate low concentration N-layer and the lower low concentration N-layer. As a result, similar to the explanation for the electric potential in FIG. 7, a smooth change is formed without forming a potential barrier or well in the electric potential so that the photoelectric conversion electrons flow smoothly from the low concentration N-layer 34 to the side of the high concentration N-layer 35 and the photoelectric conversion electrons are accumulated to the side of the high concentration N-layer 35.

Subsequently, a high concentration P-type layer 36 is formed as an element separation section in such a manner that the STI 36a is positioned at the center section of element separation in the plan width direction.

In an element separation step, using a resist pattern, which selectively opens to separate the periphery of the light receiving section region, as a mask, P-type impurity ion (B) (or indium In) is ion-implanted with the impurity concentration of 5×10¹⁶/cm³ to 1×10¹⁹/cm³, the periphery of the light receiving section is separated by an element separation region, and the periphery of the light, receiving section region is defined. In this case, the implantation for separating elements is performed in four steps in the substrate depth direction. First, the first ion implantation is performed in a region of the substrate depth ranging 0.7±0.1 μm with the implantation concentration of 2 to 6×10¹²/cm². Subsequently, the second ion implantation is performed in a region of the substrate depth ranging 1±0.1 μm with the implantation concentration of 2 to 6×10¹²/cm². Further, the third ion implantation is performed in a region of the substrate depth ranging 1.4±0.1 μm with the implantation concentration of 2 to 6×10¹²/cm² and then performed in a region of the substrate depth ranging 0.2±0.15 μm with the implantation concentration of 3 to 8×10¹²/cm². Due to this implantation, the P-type impurity is implanted into the N-type region to change the N-type region into the P-type region. The P-type impurity is implanted into the N-type region so that the N-type region is turned into the P-type region as a result of a deduction. As a result, there is no need to consider a margin for the location of ion implantation between the light receiving section and the element separation region, and the light receiving area in each light receiving section can be formed in a wider range.

Next, a gate electrode (gate 38) for reading out an electric charge is formed.

A conductivity material film is formed on a substrate section. Further, a resist pattern, which opens above a region of a photodiode including the low concentration N-layer 34 and the high concentration N-layer 35 and covers a charge readout section 33a (transistor channel section) for transferring an electric charge to the charge transfer section TF to keep the region, is used as a mask, the conductivity material film is etched, and the gate electrode (gate 38) is formed in a predetermined shape as a charge transfer electrode.

Further, the surface P+ layer 37 is formed.

In a surface P-type region forming step, in order to form an embedded photodiode, a resist pattern and a gate electrode (gate 38) are used as a mask, and boron is ion-implanted in the surface of the high concentration N-layer 35 that constitutes a photodiode. As a result, the high concentration P+ type region is formed.

Subsequently, wiring formation is carried out, and a color filter and a microlens are formed.

Although not shown in the figures, after a plurality of metal wiring sections and interlayer film sections are alternately formed, a color filter is formed above the photodiode region. Further, after a planarization film is formed, a microlens is formed in a corresponding manner to the photodiode region. As a result, a CCD type solid-state image capturing device can be manufactured.

According to Embodiment 3 with the structure described above, the low concentration N-layer 34 is formed below the high concentration N-layer 35 in the CCD type solid-state image capturing device. Therefore, even if a light receiving section area is miniaturized for a solid-state image capturing device in a next generation, the light receiving section can be expanded in volume to secure the amount of signal charges. In addition, it is possible to improve sensitivity including the color sensitivity (to improve photoelectric conversion efficiency) for green color to red color even in a deep region of the substrate, and it is possible to increase a saturation capacity (the maximum number of stored electrons). Further, because the low concentration N-layer 34 is formed below the high concentration N-layer 35, electrons in the low concentration N-layer 34 in the deep substrate flow to and accumulate on the side of the high concentration N-layer 35 and to be accumulated, reducing the conventional cross talk of signal charges to adjacent pixels.

### Embodiment 4

In Embodiment 4 of the present invention, an electronic information device will be described hereinafter. The electronic information device, such as a digital camera (e.g., digital video camera and digital still camera), an image input camera (e.g., monitoring camera, a door intercom camera, a car-mounted camera, a camera for television telephone and a camera for cell phone), a scanner, a facsimile machine and a camera-equipped cell phone device, has an image capturing section equipped with at least any of the solid-state image capturing devices according to Embodiments 1 to 3 of the present invention described above as an image input device.

The electronic information device 50 according to Embodiment 4 of the present invention includes: a signal processing section 52 for processing an image capturing signal obtained by using any of the solid-state image capturing device 51 according to Embodiment 1 to 3 described above used in an image capturing section; a memory section 53 (e.g., recording media) for recording a high-quality image data obtained from the signal processing section 52 after a predetermined signal process is performed on the image data for recording; a display section 54 (e.g., liquid crystal display device) for displaying the high-quality image data obtained from the signal processing section 52 on a display screen (e.g., liquid crystal display screen) after a predetermined signal process is performed on the image data for display; and a communication section 55 (e.g., transmitting and receiving device) for communicating the high-quality image data from the signal processing section 52 after a predetermined signal process is performed on the image data for communication. In addition, an image output section (not shown) for printing (typing out) and outputting (printing out) the high-quality image data from the signal processing section 52 may be further included, and the communication section 55 may not be included.

According to Embodiments 1 to 3 described above, by providing the low concentration N-layer below the high concentration N-layer for performing photoelectric conversion, the light receiving section can be expanded in volume by the size of the low concentration N-layer even if a light receiving region of the light receiving section is miniaturized. In addition, a photoelectric conversion electron, to which direction, such as to which substrate direction, it flows is unknown from the region of the low concentration N-layer deeper than the high concentration N-layer, can be efficiently flown from the low concentration N-layer having a lower impurity concentration to the side of the high concentration N-layer 25 to be accumulated. As a result, it is possible to improve sensitivity including the color sensitivity (to improve photoelectric conversion efficiency) for green color to red color and to reduce the cross talk of a signal charge to adjacent pixels.

Although Embodiments 2 and 3 have been described in relation to the N-type semiconductor substrates 21 and 31, the low concentration P-type wells 22 and 32, the high concentration P-type layers 23 and 33, the low concentration N-layers 24 and 34, the high concentration N-layers 25 and 35, the high concentration P-type layers 26 and 36 for separating elements, and the surface P+ layers 27 and 37, their conductivity types may be switched between the P-type and N-type. That is, they may also be the P-type semiconductor substrates 21 and 31, the low concentration N-type wells 22 and 32, the high concentration N-type layers 23 and 33, the low concentration P-layers 24 and 34, the high concentration P-layers 25 and 35, the high concentration N-type layers 26 and 36 for separating elements, and the surface N+ layers 27 and 37.

According to Embodiments 1 to 3, the multi-step implantation of the high concentration N-layer is performed in two steps for the upper impurity region and the lower impurity region therebelow, and the upper impurity region is provided in a position where the distance to the region for reading out a signal charge is shorter than that of the lower impurity region. In the low concentration N-layer, the multi step implantation for implanting ion deeply is performed in three steps for the upper impurity region, intermediate impurity region and the lower impurity region. It is not restricted to this. The multi step implantation of the high concentration N-layer may be performed in three steps or more for the upper impurity region and lower impurity regions below the upper impurity region, where the upper most impurity region is provided in a position that has the shortest distance to the region for reading out a signal charge than other lower impurity regions. In addition, the multi step implantation for implanting ion deeply in the low concentration N-layer may be performed in two steps for the upper impurity region and the lower impurity region, or the multi step implantation may be performed in three steps or more.

As described above, the present invention is exemplified by the use of its preferred Embodiments 1 to 4. However, the present invention should not be interpreted solely based on Embodiments 1 to 4 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 4 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of a solid-state image capturing device having a plurality of light receiving sections arranged in two dimensions for performing photoelectric conversion on and capturing image light from a subject; a manufacturing method for the solid-state image capturing device, and an electronic information device, such as a digital camera (e.g., digital video camera and digital still camera), an image input camera, a scanner, a facsimile machine and a camera-equipped cell phone device, having the solid-state image capturing device as an image input device used in an image capturing section of the electronic information device. A low concentration opposite conductivity layer having a impurity concentration lower than that of a high concentration opposite conductivity layer is formed below the high concentration opposite conductivity layer that constitutes a light receiving section so as to form a photodiode deep inside a substrate. Therefore, even if a light receiving section area is miniaturized for a solid-state image capturing device in a next generation, the light receiving section can be expanded in volume to secure the amount of signal charges. In addition, it is possible to improve sensitivity including the color sensitivity (to improve photoelectric conversion efficiency) for green color to red color even in a deep region of the substrate, and it is possible to increase a saturation capacity (the maximum number of stored electrons). Further, because the low concentration opposite conductivity layer is formed below the high concentration opposite conductivity layer, electrons of the low concentration opposite conductivity layer deep in the substrate flow to the side of the high concentration opposite conductivity layer and gather together, reducing the cross talk of signal charges to adjacent pixels.

Further, the impurity ion implantation is performed all together for forming a high concentration opposite conductivity layer and a low concentration opposite conductivity layer in an overall plural pixel region or a plurality of belt shaped plural pixel regions in either row or column direction. Subsequently, a single conductivity impurity ion implantation for separating pixels is performed. Therefore, there is no need to consider a margin for a shifted implant location at the time of forming the light receiving section, compared to a conventional case where a single conductivity region and an opposite conductivity region are defined in sections from the beginning and then ion implantation is performed. As a result, it is possible to form each light receiving area in a wider range.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A solid-state image capturing device having a plurality of light receiving sections for performing photoelectrical conversion on and capturing image light from a subject, wherein, in the plurality of light receiving sections, a low concentration opposite conductivity layer is provided either on a single conductivity substrate or a single conductivity layer, a high concentration opposite conductivity layer having a higher impurity concentration than the low concentration opposite conductivity layer is provided on the low concentration opposite conductivity layer, and a photodiode comprises a PN junction of the single conductivity substrate or the single conductivity layer and the low concentration opposite conductivity layer.

2. A solid-state image capturing device according to claim 1, wherein the low concentration opposite conductivity layer is added in a substrate depth direction below the high concentration opposite conductivity layer to expand a photoelectric conversion region in volume.

3. A solid-state image capturing device according to claim 1, wherein the high concentration opposite conductivity layer and the low concentration opposite conductivity layer are provided such that electric potential is inclined to flow photoelectric conversion electron from the low concentration opposite conductivity layer to the side of the high concentration opposite conductivity layer.

4. A solid-state image capturing device according to claim 2, wherein the high concentration opposite conductivity layer and the low concentration opposite conductivity layer are provided such that electric potential is inclined to flow photoelectric conversion electron from the low concentration opposite conductivity layer to the side of the high concentration opposite conductivity layer.

5. A solid-state image capturing device according to claim 1, wherein the high concentration opposite conductivity layer is provided in a region with a substrate depth of up to and including 0.5 μm.

6. A solid-state image capturing device according to claim 2, wherein the high concentration opposite conductivity layer is provided in a region with a substrate depth of up to and including 0.5 μm.

7. A solid-state image capturing device according to claim 5, wherein the low concentration opposite conductivity layer is provided in a region with a substrate depth ranging approximately 0.5 μm to 2 μm.

8. A solid-state image capturing device according to claim 6, wherein the low concentration opposite conductivity layer is provided in a region with a substrate depth ranging approximately 0.5 μm to 2 μm.

9. A solid-state image capturing device according to claim 1, wherein a depletion layer is extended to a deeper side of the single conductivity substrate or the single conductivity layer at a PN junction section between the low concentration opposite conductivity layer and the single conductivity substrate or the single conductivity layer.

10. A solid-state image capturing device according to claim 1, wherein a depletion layer is extended 2 μm to 3 μm in a depth direction side of the single conductivity substrate or the single conductivity layer at a PN junction section between the low concentration opposite conductivity layer and the single conductivity substrate or the single conductivity layer.

11. A solid-state image capturing device according to claim 4, wherein the electric potential is successively inclined gradually from an electric potential of −3 to −4 V of the high concentration opposite conductivity layer to an electric potential of less than 0V of PN junction section between the low concentration opposite conductivity layer and either the single conductivity substrate or the single conductivity layer.

12. A solid-state image capturing device according to claim 1, wherein the low concentration opposite conductivity layer includes a region where photoelectric conversion is performed on a wavelength ranging between a green color light and a red color light.

13. A solid-state image capturing device according to claim 1, wherein the single conductivity substrate or the single conductivity layer is either a silicon substrate or a silicon layer, and a thickness range of the low concentration opposite conductivity layer includes an absorption length of light ranging from green to red in silicon.

14. A solid-state image capturing device according to claim 1, wherein a multi-step implantation is performed for the high concentration opposite conductivity layer.

15. A solid-state image capturing device according to claim 14, wherein the multi step implantation is performed in two steps in a depth direction of an upper impurity region and a lower impurity region, or in three steps in a depth direction of an upper impurity region, intermediate impurity region and a lower impurity region, and the upper impurity region is provided in a position where a distance to a region for reading out a signal charge is shorter than that of the lower impurity region.

16. A solid-state image capturing device according to claim 15, wherein impurity ion implantation to the upper impurity region and the impurity region lower than the upper impurity region is performed by changing an implantation direction having a predetermined angle.

17. A solid-state image capturing device according to claim 15, wherein implantation impurity for the high concentration opposite conductivity layer has a greater mass than implantation impurity for the low concentration opposite conductivity layer.

18. A solid-state image capturing device according to claim 1, wherein implantation impurity for the high concentration opposite conductivity layer is arsenic (As), and implantation impurity for the low concentration opposite conductivity layer is phosphorus (P).

19. A solid-state image capturing device according to claim 17, wherein implantation impurity for the high concentration opposite conductivity layer is arsenic (As), and implantation impurity for the low concentration opposite conductivity layer is phosphorus (P).

20. A solid-state image capturing device according to claim 1, wherein multi step implantation is performed for the low concentration opposite conductivity layer below the high concentration opposite conductivity layer so as to perform ion implantation deeper.

21. A solid-state image capturing device according to claim 20, wherein the multi step implantation is performed in two steps in a depth direction of an upper impurity region and a lower impurity region, or in three steps in a depth direction of an upper impurity region, an intermediate impurity region and a lower impurity region.

22. A solid-state image capturing device according to claim 1, being a CMOS solid-state image capturing device, wherein the plurality of light receiving sections are provided in two dimensions in an image capturing region, a signal charge converted in each light receiving section is read out in a signal voltage converting section, and a signal amplified according to signal voltage converted in the signal voltage converting section is read out for each pixel as an output signal.

23. A solid-state image capturing device according to claim 22, wherein as a two pixel sharing structure, one signal readout circuit is commonly provided via a floating diffusion for two light receiving sections and two transfer transistors for reading out signal charges in correspondence with the two light receiving sections.

24. A solid-state image capturing device according to claim 23, wherein the signal readout circuit includes a selection transistor for selecting a predetermined light receiving section among a plurality of light receiving sections that are arranged in a matrix; an amplifying transistor connected in series to the selection transistor, for amplifying a signal in accordance with the signal voltage into which a signal charge is converted, the signal charge being transferred from a selected light receiving section to the floating diffusion via the transfer transistor; and a reset transistor for resetting electric potential of the floating diffusion to a predetermined electric potential after a signal output from the amplifying transistor.

25. A solid-state image capturing device according to claim 1, being a CCD solid-state image capturing device, wherein the plurality of light receiving sections are provided in two dimensions in an image capturing region, and a photoelectrically converted signal charge in each light receiving section is read out to a charge transfer section and successively transferred in a predetermined direction.

26. A solid-state image capturing device according to claim 1, wherein the single conductivity layer is formed as a low concentration single conductivity well layer having single conductivity impurity ion-implanted to a predetermined depth, on the opposite conductivity substrate or the opposite conductivity layer.

27. A manufacturing method for a solid-state image capturing device, comprising:
a high concentration opposite conductivity impurity ion implantation step of forming a high concentration opposite conductivity layer in a light receiving section forming region, an overall plural pixel region, or a plurality of belt shaped plural pixel regions in either row or column direction;
a low concentration opposite conductivity impurity ion implantation step of forming a low concentration opposite conductivity layer below the high concentration opposite conductivity layer in a light receiving section forming region, an overall plural pixel region, or a plurality of belt shaped plural pixel regions in either a row or a column direction; and
a pixel separation step of separating light receiving sections by selectively implanting single conductivity impurity ion with a predetermined pattern, which is performed after performing the two previous steps in either this order or a reversed order.

28. A manufacturing method for a solid-state image capturing device according to claim 27, wherein the high concentration opposite conductivity impurity ion implantation step forms a high concentration impurity layer by ion-implanting a first opposite conductivity impurity having a first impurity concentration by using a mask having openings for the overall plural pixel region, or the plurality of belt shaped plural pixel regions in either row or column direction.

29. A manufacturing method for a solid-state image capturing device according to claim 27, wherein the low concentration opposite conductivity impurity ion implantation step forms a low concentration impurity layer by ion-implanting a second opposite conductivity impurity having a first impurity concentration by using a mask having openings for the overall plural pixel region, or the plurality of belt shaped plural pixel regions in either row or column direction.

30. A manufacturing method for a solid-state image capturing device according to claim 27, wherein the pixel separation step selectively ion-implants a single conductivity impurity by using a mask having an opening to separate the periphery of the light receiving section, and separates the periphery of the light receiving section with an element separation region to define the periphery of the region of the light receiving section.

31. A manufacturing method for a solid-state image capturing device according to claim 27, further including an STI step of separating the periphery of the light receiving section with an insulation material on the single conductivity substrate or the single conductivity layer, as a preceding step of the high concentration opposite conductivity impurity ion implantation step and the low concentration opposite conductivity impurity ion implantation step.

32. A manufacturing method for a solid-state image capturing device according to claim 30, further including an STI step of separating the periphery of the light receiving section with an insulation material on the single conductivity substrate or the single conductivity layer, as a preceding step of the high concentration opposite conductivity impurity ion implantation step and the low concentration opposite conductivity impurity ion implantation step.

33. A manufacturing method for a solid-state image capturing device according to claim 31, wherein the STI step includes:
a trench groove forming step of forming a trench groove to separate the periphery of the light receiving section on the single conductivity substrate or the single conductivity layer;
a step of forming an element separating insulation film to embed the trench groove; and
a step of polishing the formed element separating insulation film to planarize a substrate surface.

34. A manufacturing method for a solid-state image capturing device according to claim 32, wherein the STI step includes:
a trench groove forming step of forming a trench groove to separate the periphery of the light receiving section on the single conductivity substrate or the single conductivity layer;
a step of forming an element separating insulation film to embed the trench groove; and
a step of polishing the formed element separating insulation film to planarize a substrate surface.

35. A manufacturing method for a solid-state image capturing device according to claim 27, further including a gate electrode forming step of forming a gate electrode for transferring an electric charge, as a post-step of the pixel separation step.

36. A manufacturing method for a solid-state image capturing device according to claim 35, further including a surface single conductivity region forming step of ion-implanting a single conductivity impurity in a surface of the high concentration opposite conductivity layer to form the surface single conductivity region.

37. An electrical information device using the solid-state image capturing device according to claim 1 as an image input device in an image capturing section.
